(19) United States
(12) Patent Application Publication
(10) Pub. No.: US 2017/0261849 A1
(43) Pub. Date: Sep. 14, 2017

(54) METHOD FOR MANUFACTURING COLOR FILTER SUBSTRATE

(71) Applicant: Shenzhen China Star Optoelectronics Technology Co., Ltd., Shenzhen City (CN)

(72) Inventor: Min Tang, Shenzhen City (CN)

(21) Appl. No.: 14/908,551

(22) PCT Filed: Dec. 23, 2015
(86) PCT No.: PCT/CN2015/098507

§ 371 Date: Jan. 29, 2016

(30) Foreign Application Priority Data
Nov. 16, 2015 (CN) 201510790976.8

(51) Int. Cl. G03F 7/00; G02F 1/1335; B41J 3/407

(52) U.S. Cl. CPC G03F 7/0007; B41J 3/407; G02F 1/133516; G02F 1/133512; G02F 1/133621; G02F 2001/133614; G02F 2202/36; G02F 2001/133357

(57) ABSTRACT

The present invention provides a method for manufacturing a color filter substrate. In the method for manufacturing a color filter substrate of the present invention, before quantum dot pastes are dropped into sub-pixel zones, photoresist barrier walls are first formed on a black matrix by means of positive photoresist to provide an effect of barrier in dropping the quantum dot paste. After the effect of barrier has been completed, the photoresist barrier walls are removed to prevent the problems of the convention color filter substrate manufacturing method that color mixture may result due to free flowing of quantum dot pastes caused by an excessively small height of the barrier walls and light leakage may result due to disorderly arrangement of liquid crystal caused by an excessively large height of barrier walls. The operation is easy and the color filter substrate so manufactured exhibits better flatness.

### BACKGROUND OF THE INVENTION

1. Field of the Invention

The present invention relates to the field of display technology, and in particular to a method for manufacturing a color filter substrate.

2. The Related Arts

Recently, with the progress of science and technology, the techniques of liquid crystal display have been continuously improved. Thin-film transistor liquid crystal displays (TFT-LCDs) take an important position among the display devices, due to quality of image displaying, low power consumption, and environmental friendliness, but the color displayed cannot cover the complete range of color gamut. Organic light-emitting diode (OLED) based display techniques that have emerged recently but are getting mature also have simple structures, reduced thickness, fast response, and capable of displaying richer colors. Further, with the advent of quantum dots, quantum dot displays have also been emerging. Since quantum dots have very narrow wavelength ranges of emission light so that the color purity is extremely high and allows for fine tuning. Compared to the conventional display monitors, newly-developed display monitors could greatly increase brightness and vividness of image and at the same time, help reduce power consumption.

Quantum dots, also referred to as nanometer crystals, are nanometer particles formed of elements of II-VI group or III-V group. The particle size of the quantum dots is generally between 1-20 nm. Due to quantum confinement of electrons and holes, a continuous energy band structure is changed into a discrete energy level structure exhibiting molecular characteristics. Thus, quantum dots, when excited by blue-violet light, are converted into monochromic light having high purity, making it possible to control color by means of the diameter of the quantum dots, and, when applied to panel display techniques, can effectively improve color gamut of a panel, providing restoration of true colors.

Nowadays, the quantum dots have been widely used in panel displaying techniques to improve the color gamut of a displaying panel. One of the main trends is to mix quantum dots with a photoresist paste to make a novel color filter film. However, the quantum dots have a high price and the cost of applying the existing photolithographic techniques to the manufacture of quantum dot color filter film is extremely high because the utilization of the quantum dots is low and quantum dots losing the capability of light conversion resulting from being easily damaged by photo initiators. Thus, the one that is considered the most feasible technique of a quantum dot color filter film is ink-jet printing (IJP) techniques.

Referring to FIGS. 1-3, in an IJP process, to prevent color mixture due to free flowing of quantum dot paste 300, a barrier wall is commonly used. As shown in FIG. 1, various patent documents propose using a black matrix (BM) 200, photo spacers (PSs), or other negative photoresists formed on a base plate 100 to serve as barrier walls. As shown in FIG. 2, if the barrier formed of the black matrix 200 is too low, the color mixture may occur easily. As shown in FIG. 3, if the barrier formed of the black matrix 200 is too high, the arrangement of liquid crystal nearby would be affected.

Thus it is desired to provide a method for manufacturing a color filter substrate to overcome the above problems.

### SUMMARY OF THE INVENTION

An object of the present invention is to provide a method for manufacturing a color filter substrate, which effectively overcomes the issue of color mixture caused by free flowing of quantum dot paste and the issue of light leakage caused by disorderly arrangement of color liquid and provides a color filter substrate manufactured therewith with better flatness.

To achieve the above object, the present invention provides a method for manufacturing a color filter substrate, which comprises the following steps:
(1) providing a base plate and forming a black matrix on the base plate such that the black matrix defines and circumferentially surrounds a plurality of sub-pixel zones on the base plate;
(2) coating positive photoresist on the black matrix and the base plate and subjecting the positive photoresist to a photolithographic operation to form photoresist barrier walls on the black matrix;
(3) providing quantum dot pastes and dropping the quantum dot pastes into the plurality of sub-pixel zones respectively;
(4) subjecting the quantum dot pastes in the plurality of sub-pixel zones to initial curing;
(5) subjecting the photoresist barrier walls to irradiation of ultraviolet light and development to remove the photoresist barrier walls and to cure the quantum dot pastes in the plurality of sub-pixel zones so as to form quantum dot layers; and
(6) coating a planarization layer on surfaces of the base plate, the black matrix, and the quantum dot layers to complete the manufacture of a color filter substrate.

In step (1), the base plate comprises a transparent plate.

In step (1), the plurality of sub-pixel zones comprises a plurality of red sub-pixel zones, a plurality of green sub-pixel zones, and a plurality of blue sub-pixel zones.

The quantum dot pastes provided in step (3) comprise red quantum dot paste and green quantum dot paste; and the red quantum dot paste and the green quantum dot paste are respectively dropped into the red and green sub-pixel zones, and the blue sub-pixel zones are kept blank.

The quantum dot layers of step (5) comprise a plurality of red quantum dot layers located in the plurality of red sub-pixel zones and a plurality of green quantum dot layers located in the plurality of green sub-pixel zones.

The color filter substrate is operable in combination with a blue backlight source such that the red quantum dot layer and the green quantum dot layer are excited by the blue backlighting to respectively emit red and green light and the blue backlighting is allowed to directly transmit through the blue sub-pixel zones to give off blue light so as to display the three primary colors of red, green, and blue to achieve color displaying.

In step (3), the quantum dot pastes are dropped into the plurality of sub-pixel zones by means of ink-jet printing.

In step (4), vacuum drying or pre-baking is applied to remove solvent from the quantum dot pastes to achieve the initial curing of the quantum dot pastes.

The pre-baking is conducted at a temperature of 80-100° C.

In step (5), baking is applied to cure the quantum dot paste.

The present invention also provides a method for manufacturing a color filter substrate, which comprises the following steps:
(1) providing a base plate and forming a black matrix on the base plate such that the black matrix defines and circumferentially surrounds a plurality of sub-pixel zones on the base plate;
(2) coating positive photoresist on the black matrix and the base plate and subjecting the positive photoresist to a photolithographic operation to form photoresist barrier walls on the black matrix;
(3) providing quantum dot pastes and dropping the quantum dot pastes into the plurality of sub-pixel zones respectively;
(4) subjecting the quantum dot pastes in the plurality of sub-pixel zones to initial curing;
(5) subjecting the photoresist barrier walls to irradiation of ultraviolet light and development to remove the photoresist barrier walls and to cure the quantum dot pastes in the plurality of sub-pixel zones so as to form quantum dot layers; and
(6) coating a planarization layer on surfaces of the base plate, the black matrix, and the quantum dot layers to complete the manufacture of a color filter substrate;
wherein in step (1), the base plate comprises a transparent plate;
wherein in step (1), the plurality of sub-pixel zones comprises a plurality of red sub-pixel zones, a plurality of green sub-pixel zones, and a plurality of blue sub-pixel zones;
wherein in step (3), the quantum dot pastes are dropped into the plurality of sub-pixel zones by means of ink-jet printing;
wherein in step (4), vacuum drying or pre-baking is applied to remove solvent from the quantum dot pastes to achieve the initial curing of the quantum dot pastes; and
wherein in step (5), baking is applied to cure the quantum dot paste.

The efficacy of the present invention is that the present invention provides a method for manufacturing a color filter substrate, wherein before quantum dot pastes are dropped into sub-pixel zones, photoresist barrier walls are first formed on a black matrix by means of positive photoresist to provide an effect of barrier in dropping the quantum dot paste. After the effect of barrier has been completed, the photoresist barrier walls are removed to prevent the problems of the convention color filter substrate manufacturing method that color mixture may result due to free flowing of quantum dot pastes caused by an excessively small height of the barrier walls and light leakage may result due to disorderly arrangement of liquid crystal caused by an excessively large height of barrier walls. The operation is easy and the color filter substrate so manufactured exhibits better flatness.

### BRIEF DESCRIPTION OF THE DRAWINGS

The technical solution, as well as other beneficial advantages, of the present invention will become apparent from the following detailed description of an embodiment of the present invention, with reference to the attached drawings.

In the drawings:

FIG. 1 is a schematic view illustrating a manufacturing method of a conventional color filter substrate;

FIG. 2 is a schematic view illustrating color mixture caused by free flowing of quantum dot paste occurring in a manufacturing method of a conventional color filter substrate;

FIG. 3 is a schematic view illustrating light leakage resulting from disorderly arrangement of liquid crystal occurring in a conventional color filter substrate;

FIG. 4 is a flow chart illustrating a method for manufacturing a color filter substrate according to the present invention;

FIG. 5 is a schematic view illustrating step 1 of the method for manufacturing a color filter substrate according to the present invention;

FIG. 6 is a schematic view illustrating step 2 of the method for manufacturing a color filter substrate according to the present invention;

FIG. 7 is a schematic view illustrating step 3 of the method for manufacturing a color filter substrate according to the present invention;

FIG. 8 is a schematic view illustrating step 4 of the method for manufacturing a color filter substrate according to the present invention;

FIG. 9 is a schematic view illustrating step 5 of the method for manufacturing a color filter substrate according to the present invention; and

FIG. 10 is a schematic view illustrating step 6 of the method for manufacturing a color filter substrate according to the present invention.

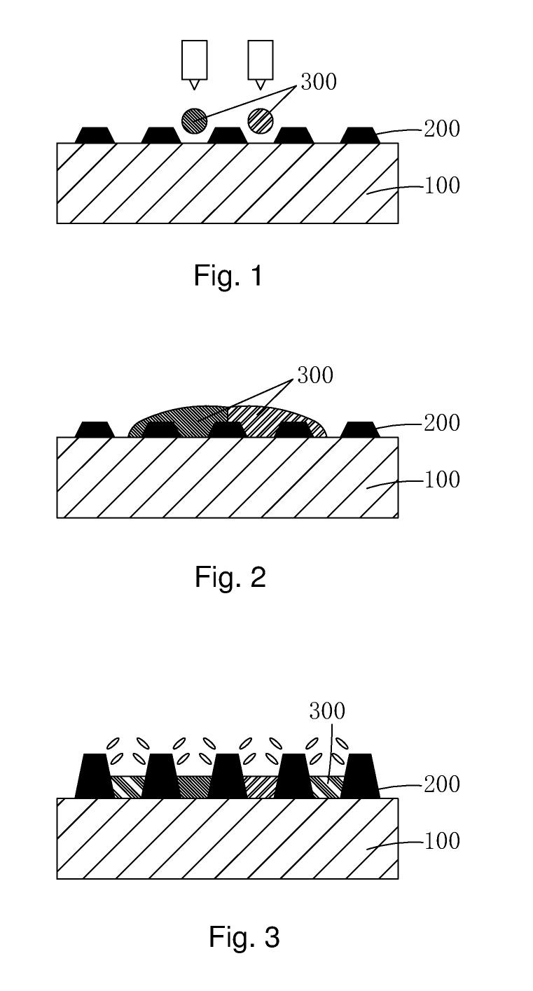

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

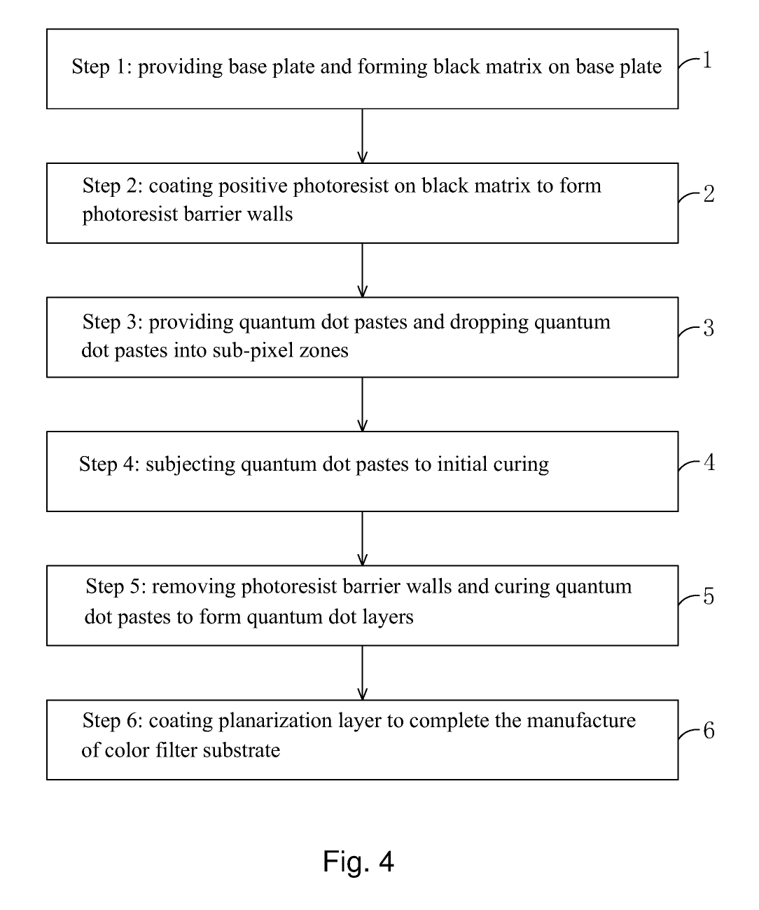

Referring to FIG. 4, the present invention provides a method for manufacturing a color filter substrate, which comprises the following steps:

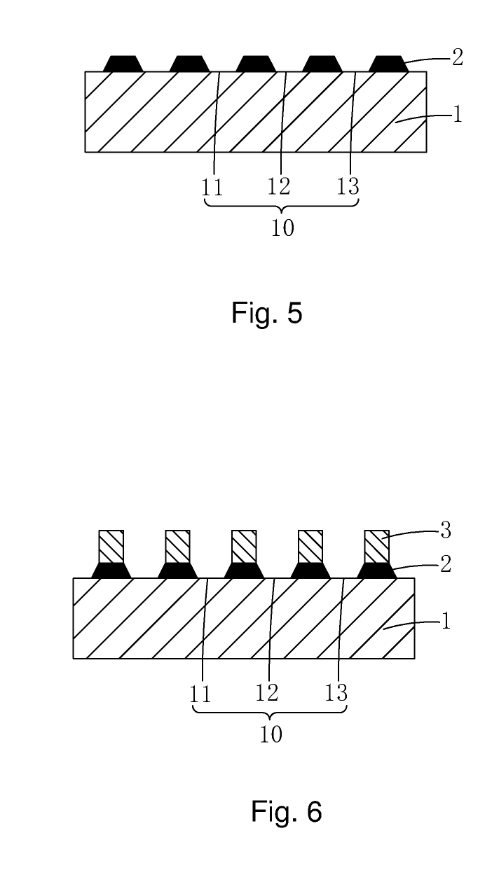

Step 1: as shown in FIG. 5, providing a base plate 1 and forming a black matrix 2 on the base plate 1 such that the black matrix 2 defines and circumferentially surrounds a plurality of sub-pixel zones 10 on the base plate 1.

Specifically, the base plate 1 comprises a transparent plate, preferably a glass plate.

Specifically, the plurality of sub-pixel zones 10 comprises a plurality of red sub-pixel zones 11, a plurality of green sub-pixel zones 12, and a plurality of blue sub-pixel zones 13.

Step 2: as shown in FIG. 6, coating positive photoresist on the black matrix 2 and the base plate 1 and subjecting the positive photoresist to a photolithographic operation to form photoresist barrier walls 3 on the black matrix 2.

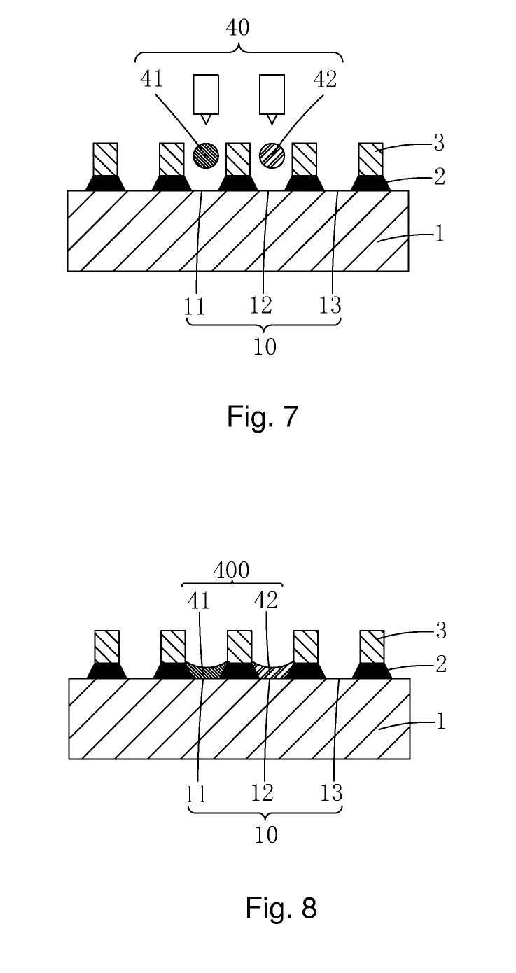

Step 3: as shown in FIG. 7, providing quantum dot pastes 40 and dropping the quantum dot pastes 40 into the plurality of sub-pixel zones 10 respectively.

Specifically, the quantum dot pastes 40 comprise a mixture comprising quantum dots, paste material, and solvent.

Specifically, the paste is water-soluble paste and the solvent is water-soluble solvent; or alternatively, the paste is oil-soluble paste and the solvent is oil-soluble solvent. Specifically, the quantum dot pastes 40 include red quantum dot paste 41 and the green quantum dot paste 42. The red and green sub-pixel zones 11, 12 respectively receive the red quantum dot paste 41 and the green quantum dot paste 42 to drop therein, while the blue sub-pixel zones 13 are kept blank.

Specifically, the quantum dot pastes 40 are dropped into the plurality of sub-pixel zones 10 by means of ink-jet printing.

Step 4: as shown in FIG. 8, subjecting the quantum dot pastes 40 in the plurality of sub-pixel zones 10 to initial curing.

Specifically, Step 4 uses vacuum drying or pre-baking to remove the solvent from the quantum dot pastes 40 to achieve the initial curing of the quantum dot paste 40.

Specifically, the pre-baking is conducted at a temperature of 80-100° C.

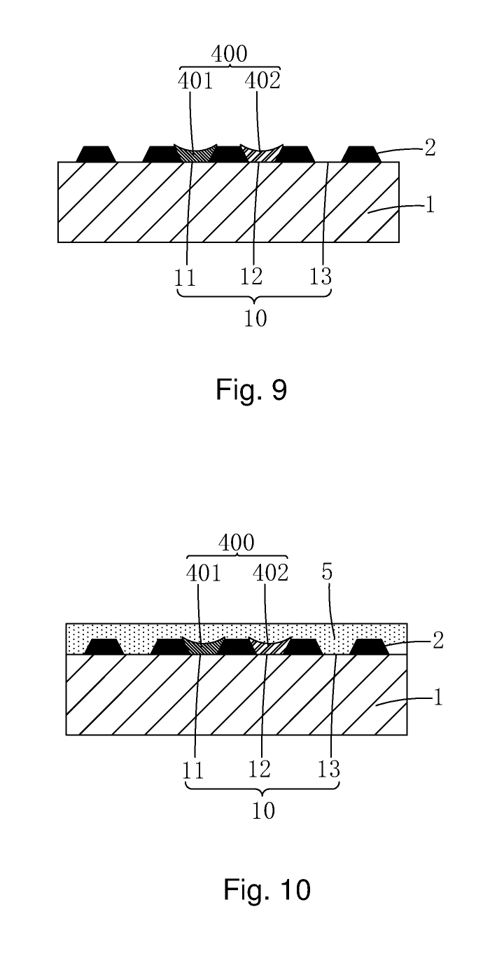

Step 5: as shown in FIG. 9, subjecting the photoresist barrier walls 3 to irradiation of ultraviolet light and development to remove the photoresist barrier walls 3 and to cure the quantum dot pastes 40 in the plurality of sub-pixel zones 10 so as to form quantum dot layers 400.

Specifically, the quantum dot layers 400 comprise red quantum dot layers 401 located in the red sub-pixel zones 11 and green quantum dot layers 402 located in the green sub-pixel zones 12.

Specifically, Step 5 uses a baking operation to cure the quantum dot paste 40.

Specifically, the baking is conducted at a temperature of 100-150° C.

Step 6: as shown in FIG. 10, coating a planarization layer 5 on surfaces of the base plate 1, the black matrix 2, and the quantum dot layers 400 to complete the manufacture of a color filter substrate.

Specifically, the planarization layer 5 is formed of a transparent material.

Specifically, the color filter substrate is used in combination with a blue backlight source. The red quantum dot layer 401 and the green quantum dot layer 402 are respectively excited by the blue backlighting to emit red and green light and the blue backlighting is allowed to directly transmit through the blue sub-pixel zones 13 to give off blue light so as to display the three primary colors of red, green, and blue to achieve color displaying. The color filter substrate is applicable to in-plane switching type, vertical alignment type, or twisted nematic type liquid crystal display panels.

In summary, the present invention provides a method for manufacturing a color filter substrate, wherein before quantum dot pastes are dropped into sub-pixel zones, photoresist barrier walls are first formed on a black matrix by means of positive photoresist to provide an effect of barrier in dropping the quantum dot paste. After the effect of barrier has been completed, the photoresist barrier walls are removed to prevent the problems of the convention color filter substrate manufacturing method that color mixture may result due to free flowing of quantum dot pastes caused by an excessively small height of the barrier walls and light leakage may result due to disorderly arrangement of liquid crystal caused by an excessively large height of barrier walls. The operation is easy and the color filter substrate so manufactured exhibits better flatness.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing a color filter substrate, comprising the following steps:
(1) providing a base plate and forming a black matrix on the base plate such that the black matrix defines and circumferentially surrounds a plurality of sub-pixel zones on the base plate;
(2) coating positive photoresist on the black matrix and the base plate and subjecting the positive photoresist to a photolithographic operation to form photoresist barrier walls on the black matrix;
(3) providing quantum dot pastes and dropping the quantum dot pastes into the plurality of sub-pixel zones respectively;
(4) subjecting the quantum dot pastes in the plurality of sub-pixel zones to initial curing;
(5) subjecting the photoresist barrier walls to irradiation of ultraviolet light and development to remove the photoresist barrier walls and to cure the quantum dot pastes in the plurality of sub-pixel zones so as to form quantum dot layers; and
(6) coating a planarization layer on surfaces of the base plate, the black matrix, and the quantum dot layers to complete the manufacture of a color filter substrate.

2. The method for manufacturing a color filter substrate as claimed in claim 1, wherein in step (1), the base plate comprises a transparent plate.

3. The method for manufacturing a color filter substrate as claimed in claim 1, wherein in step (1), the plurality of sub-pixel zones comprises a plurality of red sub-pixel zones, a plurality of green sub-pixel zones, and a plurality of blue sub-pixel zones.

4. The method for manufacturing a color filter substrate as claimed in claim 3, wherein the quantum dot pastes provided in step (3) comprise red quantum dot paste and green quantum dot paste; and the red quantum dot paste and the green quantum dot paste are respectively dropped into the red and green sub-pixel zones, and the blue sub-pixel zones are kept blank.

5. The method for manufacturing a color filter substrate as claimed in claim 4, wherein the quantum dot layers of step (5) comprise a plurality of red quantum dot layers located in the plurality of red sub-pixel zones and a plurality of green quantum dot layers located in the plurality of green sub-pixel zones.

6. The method for manufacturing a color filter substrate as claimed in claim 5, wherein the color filter substrate is operable in combination with a blue backlight source such that the red quantum dot layer and the green quantum dot layer are excited by the blue backlighting to respectively emit red and green light and the blue backlighting is allowed to directly transmit through the blue sub-pixel zones to give off blue light so as to display the three primary colors of red, green, and blue to achieve color displaying.

7. The method for manufacturing a color filter substrate as claimed in claim 1, wherein in step (3), the quantum dot pastes are dropped into the plurality of sub-pixel zones by means of ink-jet printing.

8. The method for manufacturing a color filter substrate as claimed in claim 1, wherein in step (4), vacuum drying or pre-baking is applied to remove solvent from the quantum dot pastes to achieve the initial curing of the quantum dot pastes.

9. The method for manufacturing a color filter substrate as claimed in claim 8, wherein the pre-baking is conducted at a temperature of 80-100° C.

10. The method for manufacturing a color filter substrate as claimed in claim 1, wherein in step (5), baking is applied to cure the quantum dot paste.

11. A method for manufacturing a color filter substrate, comprising the following steps:
(1) providing a base plate and forming a black matrix on the base plate such that the black matrix defines and circumferentially surrounds a plurality of sub-pixel zones on the base plate;
(2) coating positive photoresist on the black matrix and the base plate and subjecting the positive photoresist to a photolithographic operation to form photoresist barrier walls on the black matrix;
(3) providing quantum dot pastes and dropping the quantum dot pastes into the plurality of sub-pixel zones respectively;
(4) subjecting the quantum dot pastes in the plurality of sub-pixel zones to initial curing;
(5) subjecting the photoresist barrier walls to irradiation of ultraviolet light and development to remove the photoresist barrier walls and to cure the quantum dot pastes in the plurality of sub-pixel zones so as to form quantum dot layers; and
(6) coating a planarization layer on surfaces of the base plate, the black matrix, and the quantum dot layers to complete the manufacture of a color filter substrate;
wherein in step (1), the base plate comprises a transparent plate;
wherein in step (1), the plurality of sub-pixel zones comprises a plurality of red sub-pixel zones, a plurality of green sub-pixel zones, and a plurality of blue sub-pixel zones;
wherein in step (3), the quantum dot pastes are dropped into the plurality of sub-pixel zones by means of ink-jet printing;
wherein in step (4), vacuum drying or pre-baking is applied to remove solvent from the quantum dot pastes to achieve the initial curing of the quantum dot pastes; and
wherein in step (5), baking is applied to cure the quantum dot paste.

12. The method for manufacturing a color filter substrate as claimed in claim 11, wherein the quantum dot pastes provided in step (3) comprise red quantum dot paste and green quantum dot paste; and the red quantum dot paste and the green quantum dot paste are respectively dropped into the red and green sub-pixel zones, and the blue sub-pixel zones are kept blank.

13. The method for manufacturing a color filter substrate as claimed in claim 12, wherein the quantum dot layers of step (5) comprise a plurality of red quantum dot layers located in the plurality of red sub-pixel zones and a plurality of green quantum dot layers located in the plurality of green sub-pixel zones.

14. The method for manufacturing a color filter substrate as claimed in claim 13, wherein the color filter substrate is operable in combination with a blue backlight source such that the red quantum dot layer and the green quantum dot layer are excited by the blue backlighting to respectively emit red and green light and the blue backlighting is allowed to directly transmit through the blue sub-pixel zones to give off blue light so as to display the three primary colors of red, green, and blue to achieve color displaying.

15. The method for manufacturing a color filter substrate as claimed in claim 11, wherein the pre-baking is conducted at a temperature of 80-100° C.
